(19) United States
(12) Patent Application Publication
(10) Pub. No.: US 2016/0104934 A1
(43) Pub. Date: Apr. 14, 2016

(54) ANTENNA, ANTENNA PACKAGE, AND COMMUNICATIONS MODULE

(71) Applicant: Samsung Electro-Mechanics Co., Ltd., Suwon-si (KR)

(72) Inventors: Seung Goo JANG, Suwon-si (KR); Se Min JIN, Suwon-si (KR); Eun Kyoung KIM, Suwon-si (KR); Min Hoon KIM, Suwon-si (KR); Hyung Geun JI, Suwon-si (KR); Jae Hyun CHANG, Suwon-si (KR)

(73) Assignee: SAMSUNG ELECTRO-MECHANICS CO., LTD., Suwon-si (KR)

(21) Appl. No.: 14/879,380

(22) Filed: Oct. 9, 2015

(30) Foreign Application Priority Data
Oct. 10, 2014 (KR) 10-2014-0136912
Jan. 30, 2015 (KR) 10-2015-0015597

(51) Int. Cl. H01Q 1/38; H05K 3/46; H01Q 15/14

(52) U.S. Cl. CPC H01Q 1/38; H01Q 15/14; H05K 3/46; H01Q 15/141

(57) ABSTRACT

An antenna includes: a board including layers; a main antenna pattern formed on a layer among the layers, and including two main patterns spaced apart from each other; and dummy patterns formed in the board and insulated from the main antenna pattern.

### CROSS-REFERENCE TO RELATED APPLICATION(S)

This application claims the benefit of Korean Patent Application No. 10-2014-0136912 filed on Oct. 10, 2014 and Korean Patent Application No. 10-2015-0015597 filed on Jan. 30, 2015, in the Korean Intellectual Property Office, the entire disclosures of which are incorporated herein by reference for all purposes.

### BACKGROUND

1. Field

The following description relates to an antenna, an antenna package, and a communications module.

2. Description of Related Art

To date, communications systems have mainly used signals within the ultra high frequency (UHF) band. However, in future, new communications systems for high speed data transmissions will use signals within an extremely high frequency (EHF) band, such as the 60 GHz band used for communications using the 802.11 ad standard.

Such a communications system using the EHF band uses signals within a wide bandwidth, about 10 to 100 times wider than a bandwidth used in communications systems using signals within the UHF band for high speed data transmissions. However, unlike general communications systems using signals within the UHF band, communications systems using signals within an EHF band, such as the 60 GHz band, may have problems such as large transfer loss caused by a high frequency, such that a plurality of antennas may be required. Therefore, in communications systems using signals within the EHF band, the plurality of antennas are packaged to be embedded in a printed circuit board.

However, a printed circuit board having a multilayer structure has a degree of EHF band loss which may be relatively greater than that of other types of board, such as a low temperature co-fired ceramic (LTCC) board. A printed circuit board also has a relatively low number of layers, causing limitations on an antenna structure. Accordingly, antenna performance such as wideband characteristics, or the like, required for high speed data transmissions, may be deteriorated with antennas embedded in a printed circuit board.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, an antenna includes: a board including layers; an antenna pattern formed on a layer among the layers and including two patterns spaced apart from each other; and dummy patterns formed in the board and insulated from the antenna pattern.

Virtual extension lines of the two main patterns, which extend in a length direction of the two main patterns, may coincide with each other.

Neighboring patterns among the dummy patterns may be spaced apart from each other by a predetermined distance.

Each of the dummy patterns may include two sides forming a predetermined angle with respect to each other. One of the two sides of a first dummy pattern among the dummy patterns and one of the two sides of a second dummy pattern adjacent to the first dummy pattern face each other in parallel with each other.

The antenna may further include at least one auxiliary antenna pattern formed on another layer among the layers that is higher than the layer on which the main antenna pattern is formed.

The auxiliary antenna pattern may include two auxiliary patterns spaced apart from each other.

The two auxiliary patterns and the two main patterns may be overlapped with each other in a stacking direction of the layers.

The antenna may further include a reflecting pattern formed on a layer among the layers that is lower than the layer on which the main antenna pattern is formed.

The antenna may further include signal input pattern to which a control signal from a radio frequency integrated circuit is input.

The antenna may further include vias forming a power supply path from the signal input pattern to the main antenna pattern.

The two main patterns may include first and second patterns, and the main antenna pattern may further include third and fourth patterns positioned on virtual lines intersecting an intersection point of virtual extension lines of the first and second patterns.

The antenna may further include an auxiliary antenna pattern formed on a layer that is higher than the layer on which the main antenna pattern is formed and including four auxiliary patterns overlapped with the first through fourth patterns in a stacking direction.

According to another general aspect, an antenna package includes antennas, wherein each antenna among the antennas includes: a board including layers; an antenna pattern formed on a layer among the layers and including two patterns spaced apart from each other; and dummy patterns insulated from the antenna pattern.

The antennas may be arrayed such that virtual extension lines of the two patterns of respective neighboring antennas, among the antennas, coincide with each other.

The antennas may be arrayed such that the antennas are positioned on diagonal lines, and virtual extension lines of the two patterns of respective neighboring antennas, among the antennas, coincide with each other.

According to another general aspect, a method of manufacturing an antenna includes: disposing a main antenna pattern on a layer among layers of a board, the main antenna pattern including two main patterns spaced apart from each other; and disposing dummy patterns in the board, the dummy patterns being insulated from the main antenna pattern.

The method may further include: disposing an auxiliary antenna pattern on another layer among the layers, the auxiliary antenna pattern including two auxiliary patterns spaced apart from each other; and arranging the two auxiliary patterns and the two main patterns to be overlapped with each other in a stacking direction of the layers.

Other features and aspects will be apparent from the following detailed description, the drawings, and the claims.

### BRIEF DESCRIPTION OF THE DRAWINGS

FIG. 1 is a cross-sectional view illustrating an example of an antenna.

FIGS. 2A and 2B are views illustrating examples of main antenna patterns.

FIGS. 3A through 3C are views illustrating examples of dummy patterns.

FIGS. 4A and 4B are views illustrating examples of main antenna patterns and dummy patterns.

FIGS. 5A and 5B are views illustrating examples of power supply patterns.

FIGS. 6A and 6B are cross-sectional views illustrating additional examples of antennas.

FIG. 7 is a view illustrating an example of a reflecting pattern.

FIGS. 8A through 8E are cross-sectional views illustrating further examples of antennas.

FIGS. 9A and 9B are views illustrating examples of auxiliary antenna patterns.

FIGS. 10A and 10B are views illustrating examples of auxiliary antenna patterns and dummy patterns.

FIGS. 11 A and 11 B are perspective views illustrating examples of antennas provided by combining layers.

FIG. 12 is a graph illustrating a simulation result of an example antenna.

FIGS. 13A through 14C are views illustrating radiation characteristics of example antennas.

FIGS. 15A and 15B are schematic views illustrating example antenna packages.

FIG. 16 is an example circuit diagram of a communications module including an antenna.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

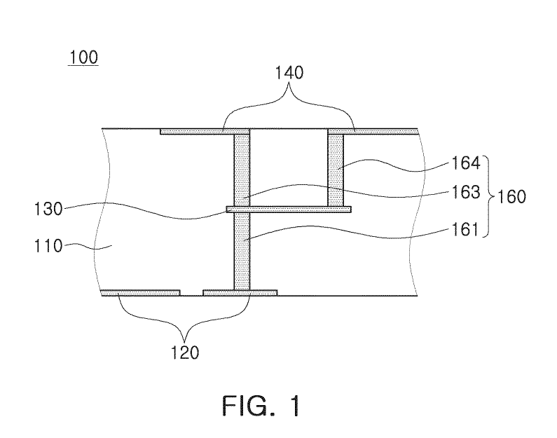

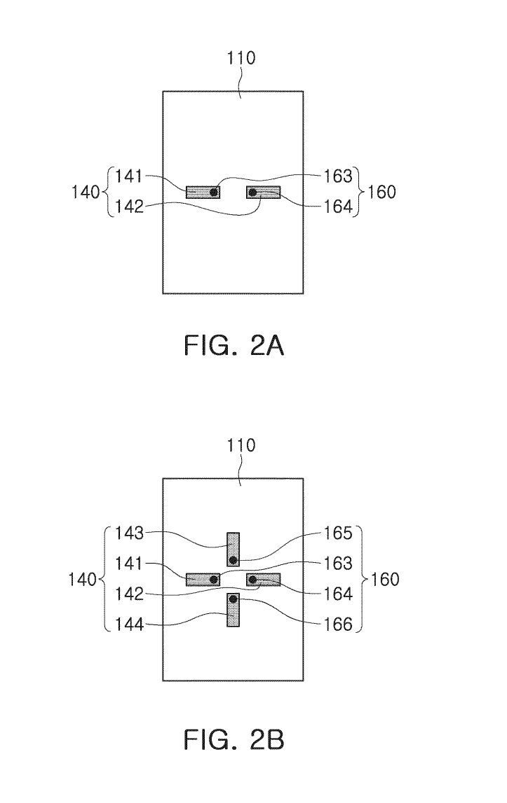

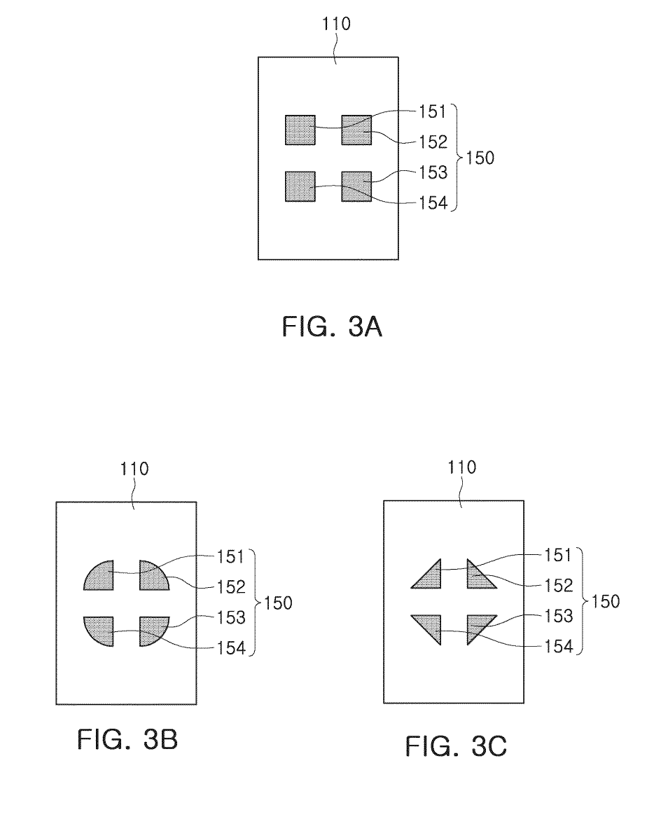

FIG. 1 is a cross-sectional view illustrating an example of an antenna 100. FIGS. 2A through 3C are views illustrating examples of a main layer of FIG. 1.

Referring to FIGS. 1 through 3C, an antenna 100, according to an example, includes a board 110, a signal input pattern 120, a power supply pattern 130, a main antenna pattern 140, and vias 160 provided in the board 110.

The board 110 is a multilayer board including a plurality of layers, and may be at least one of a ceramic board, a printed circuit board, and a flexible board.

For convenience of explanation, in the board 110, a layer on which the signal input pattern 120 is formed will be referred to as a first layer, a layer on which the power supply pattern 130 is formed will be referred to as a second layer, and a layer on which the main antenna pattern 140 is formed will be referred to as a third layer.

The signal input pattern 120 is formed on the first layer of the board 110, which is the lowest layer of the board 110, and receives a predetermined control signal provided externally. Although not illustrated in FIG. 1, the signal input pattern 120 may receive the predetermined control signal through a radio frequency integrated circuit using a conductive ball electrically connected thereto.

The vias 160 electrically connect respective layers. For example, a first via 161 and a second via (not illustrated) connect the signal input pattern 120 and the power supply pattern 130 to each other, and, as illustrated in FIGS. 2A and 2B, third and fourth vias 163 and 164 and fifth and sixth vias 165 and 166 connect the power supply pattern 130 and the main antenna pattern 140.

FIGS. 2A and 2B are views illustrating examples of main antenna patterns 140.

Referring to FIGS. 1 through 2B, the main antenna pattern 140 is formed on the third layer of the board 110 to provide a predetermined radiation part.

Referring to FIG. 2A, the main antenna pattern 140 may include two main patterns 141 and 142 connected to two vias 163 and 164, respectively. A first main pattern 141 may be connected to the third via 163, and a second main pattern 142 may be connected to the fourth via 164. The first and second main patterns 141 and 142 may be spaced apart from each other by a predetermined distance. In a case in which the first and second main patterns 141 and 142 are extended in a length direction, virtual extension lines of the first and second main patterns 141 and 142 may coincide with each other.

Lengths of the first and second main patterns 141 and 142 may determine a resonance frequency. For example, each of the two main patterns 141 and 142 may have a length equal to a half of a wavelength of a signal used with a communications frequency of the antenna 100.

Referring to FIG. 2B, the main antenna pattern 140 may further include third and fourth main patterns 143 and 144. The third main pattern 143 is connected to the fifth via 165, and the fourth main pattern 144 is connected to the sixth via 166.

The third and fourth main patterns 143 and 144 may be spaced apart from each other by a predetermined distance. In a case in which the third and fourth main patterns 143 and 144 are extended in the length direction, virtual extension lines of the third and fourth main patterns 143 and 144 may coincide with each other.

The virtual extension lines of the first and second main patterns 141 and 142 intersect virtual extension lines of the third and fourth main patterns 143 and 144. For instance, the first to fourth main patterns 141 to 144 may be spaced apart from an intersection point of two virtual lines intersecting each other by a predetermined distance.

Lengths of the third and fourth main patterns 143 and 144 may determine a resonance frequency. For example, each of the two main patterns 143 and 144 may have a length equal to a half of a wavelength of a signal used with a communications frequency of the antenna 100. In a case of forming the main antenna pattern 140 illustrated in FIG. 2B, a package size is not increased, such that space utilization efficiency is increased.

FIGS. 3A through 3C are views of dummy patterns 150 according to various examples. The number of dummy patterns 150 may be at least one. The dummy pattern 150 may be formed on a layer the same as or different than a layer on which the main antenna pattern 140 is formed, and be formed on one or more layers.

Referring to FIGS. 3A through 3C, neighboring patterns among dummy patterns 151 to 154 may be spaced apart from each other by a predetermined distance. Each of the dummy patterns 151 to 154 may have two sides forming a predetermined angle with respect to each other, and one of the two sides of one of the dummy patterns 151 to 154 and one of the two sides of another dummy pattern adjacent thereto, among the dummy patterns 151 to 154, may face each other while being disposed parallel with respect to each other. For example, the predetermined angle may be 90 degrees.

Referring to FIGS. 3A through 3C, each of the dummy patterns 151 to 154 may, for example, have a quadrangular shape, a quadrisected circle shape, or a triangular shape, or another shape.

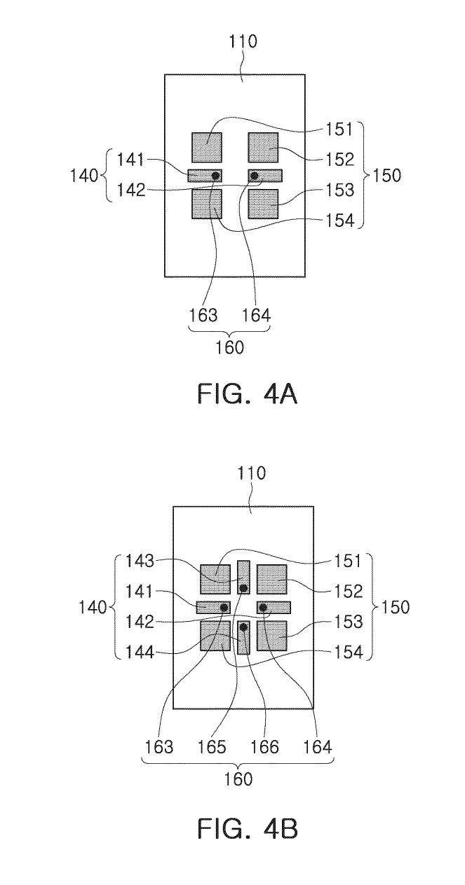

FIGS. 4A and 4B are views illustrating examples of main antenna patterns 140 and dummy patterns 150.

Although FIGS. 4A and 4B illustrate a combination of the main antenna patterns 140 of FIGS. 2A and 2B and the dummy patterns 150 of FIG. 3A in which the dummy patterns 150 are formed on the same layer as a layer on which the main antenna patterns 140 are formed, the dummy patterns 150 may be formed on a layer different than the layer on which the main antenna patterns 140 are formed. In addition, the main antenna patterns 140 of FIGS. 2A and 2B may be combined with the dummy patterns of FIGS. 3B and 3C.

The dummy patterns 151 to 154 may be spaced apart from sides of the main patterns 141 to 144 by predetermined distances in length directions of the main patterns 141 to 144, respectively. For example, the dummy patterns 151 to 154 may be disposed to be spaced apart from sides of the main patterns 141 to 144 by a distance equal to 1/10 of the wavelength of the signal used with the communications frequency of the antenna 100, in the length directions of the main patterns 141 to 144, respectively. As described above, each of the dummy patterns 151 to 154 may have two sides forming a predetermined angle with respect to each other. A length of each of the two sides may be a length equal to 90 to 95% of a length of each of sides of the main patterns 141 and 142 in the length direction of the main pattern.

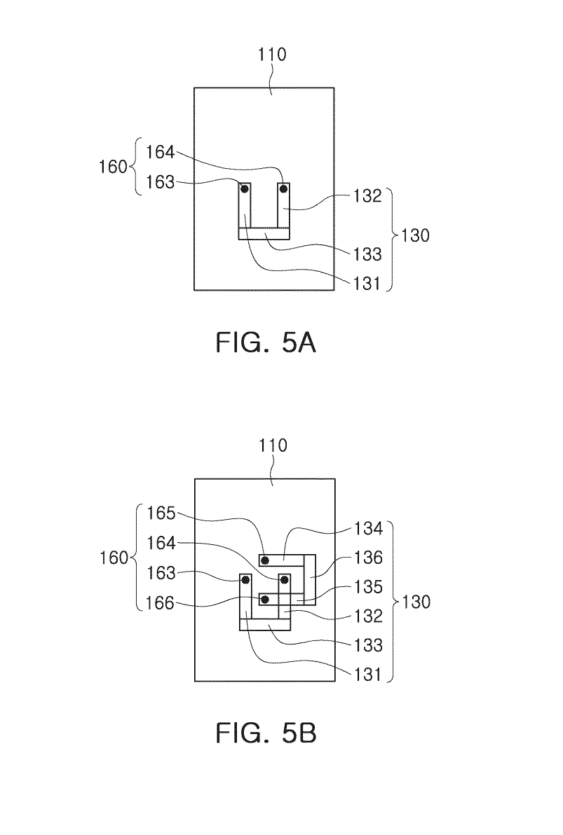

FIGS. 5A and 5B are views illustrating examples of power supply patterns 130 according.

The power supply pattern 130 illustrated in FIG. 5A corresponds to the main antenna pattern 140 illustrated in FIG. 2A, and the power supply pattern 130 illustrated in FIG. 5B corresponds to the main antenna pattern 140 illustrated in FIG. 2B.

First, referring to FIG. 5A, the power supply pattern 130 includes three power supply line patterns 131 to 133 connected to each other to form a “ [symbol] ” shape. For example, each of two power supply line patterns 131 and 132 facing each other may have a length equal to ¼ of the wavelength of the signal used with the communications frequency of the antenna 100, and one line pattern 133 connecting the two power supply line patterns 131 and 132 to each other may have a length equal to ½ of the wavelength of the signal used with the communications frequency of the antenna 100.

The first via 161 (FIG. 1) may be connected to one of first to third power supply line patterns 131 to 133, the first power supply line pattern 131 is connected to the third via 163, and the second power supply line pattern 132 is connected to the fourth via 164.

Referring to FIG. 5B, the power supply pattern 130 may further include three power supply line patterns 134 to 136 connected to each other to form a “ [symbol] ” shape, as compared with the power supply pattern 130 as illustrated in FIG. 5A. For example, each of two power supply line patterns 134 and 135 facing each other may have a length equal to ¼ of the wavelength of the signal used with the communications frequency of the antenna 100, and one line pattern 136 connecting the two power supply line patterns 134 and 135 to each other may have a length equal to ¼ of the wavelength of the signal used with the communications frequency of the antenna 100.

The second via (not shown) may be connected to one of fourth to sixth power supply line patterns 134 to 136, the fourth power supply line pattern 134 is connected to the fifth via 165, and the fifth power supply line pattern 135 is connected to the sixth via 166.

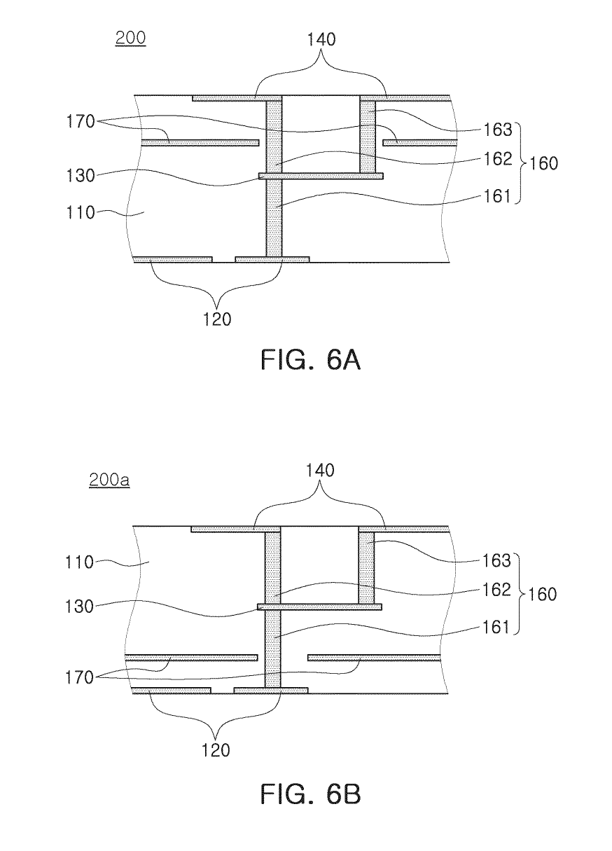

FIGS. 6A and 6B are cross-sectional views illustrating examples of antennas 200 and 200a, respectively.

In the discussion of antennas 200 and 200a of FIGS. 6A and 6B, a detailed description of components that are the same as those of the antenna 100 of FIG. 1 will be omitted, and components that are added to or modified from those of the antenna 100 of FIG. 1 will mainly be described.

Referring to FIGS. 6A and 6B, antennas 200 and 200a further include a reflecting pattern 170.

For example, when a radio frequency signal generated in a radiation part formed by the main antenna pattern 140 is output upwardly based on FIGS. 6A and 6B, the reflecting pattern 170 may be formed on a layer that is lower than the third layer on which the main antenna pattern 140 is formed, thereby improving directivity of the radio frequency signal.

Referring to FIG. 6A, in the antenna 200, the reflecting pattern 170 is formed on a layer between the power supply pattern 130 and the main antenna pattern 140, for example, interposed between second and third layers. Referring to FIG. 6B, in the antenna 200a, the reflecting pattern 170 is formed on a layer between the signal input pattern 120 and the power supply pattern 130, for example, interposed between third and fourth layers.

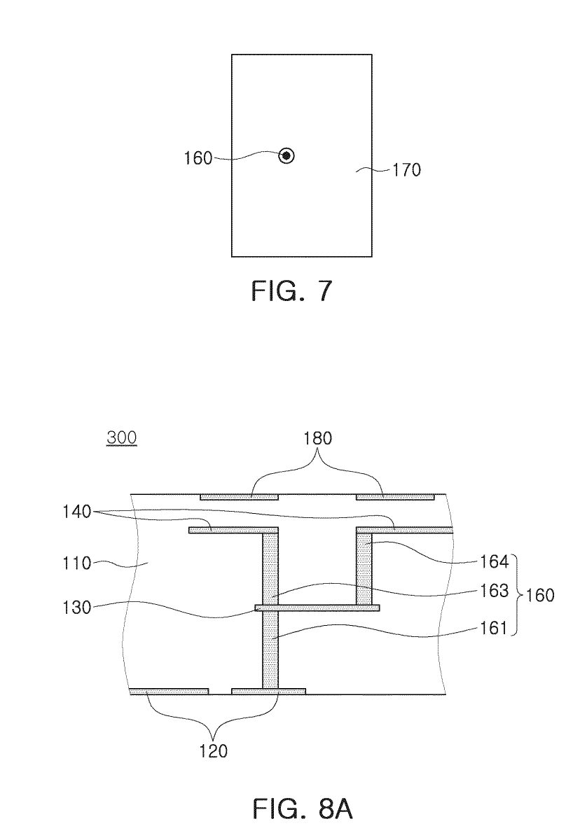

FIG. 7 is a view illustrating the reflecting pattern according to an example. Referring to FIG. 7, the reflecting pattern 170 has a flat shape, but is partially removed to thereby be insulated from the via 160 penetrating between layers of the board 110. That is, the reflecting pattern 170 is configured such that it does not contact the via 160. For example, the reflecting pattern 170 may be connected to a ground.

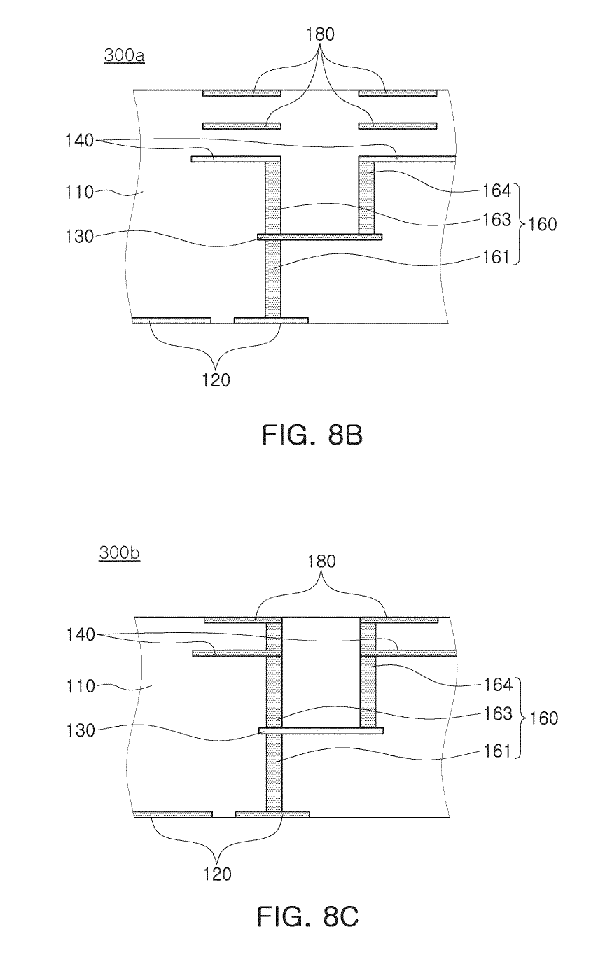

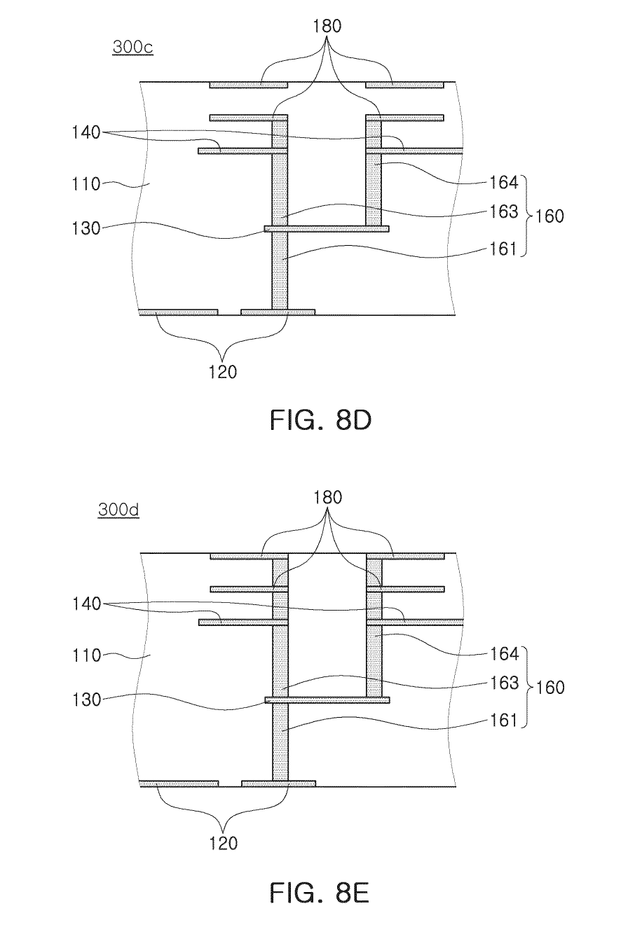

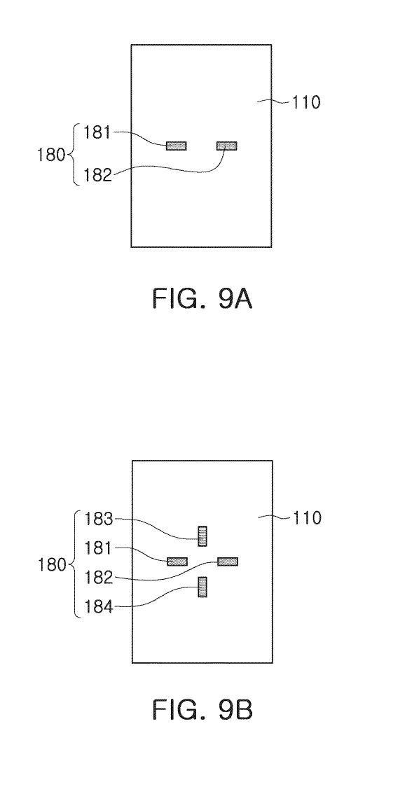

FIGS. 8A through 8E are cross-sectional views illustrating examples of antennas 300-300d. FIGS. 9A and 9B are views illustrating examples of auxiliary antenna patterns 180.

In the antennas of FIGS. 8A though 8E, a detailed description of components that are the same as those of the antenna 100 of FIG. 1 will be omitted, and components added to or modified from those of the antenna 100 of FIG. 1 will mainly be described.

Referring to FIGS. 8A through 8E, example antennas 300-300d further include an auxiliary antenna pattern 180.

The auxiliary antenna pattern 180 is formed on at least one layer. More specifically, the auxiliary antenna pattern 180 may be formed on a layer that is higher than a layer on which the main antenna pattern 140 is formed. The auxiliary antenna pattern 180 may be formed on a fourth layer that is higher than the third layer, as illustrated in the antenna 300 of FIG. 8A, or be formed on fourth and fifth layers higher than the third layer, as illustrated in the antenna 300a of FIG. 8B. Alternatively, the auxiliary antenna patterns 180 may be formed on three or more layers.

Referring to FIGS. 8C through 8E, two vias 163 and 164 may be electrically connected to the auxiliary antenna pattern 180 through the main antenna pattern 140. In a case in which the auxiliary antenna patterns 180 are formed on a plurality of layers, the two vias 163 and 164 may be connected to the auxiliary antenna pattern 180 formed on at least one layer.

For example, the two vias 163 and 164 may be connected to the auxiliary antenna pattern 180 formed on the fourth layer, as illustrated in the antenna 300b of FIG. 8C, and may not be connected to the auxiliary antenna pattern 180 formed on the fifth layer, as illustrated in the antenna 300c of FIG. 8D. Alternatively, the two vias 163 and 164 may be connected to both of the auxiliary antenna patterns 180 formed on the fourth and fifth layers, as illustrated in the antenna 300d of FIG. 8E.

FIGS. 9A and 9B are views illustrating examples of auxiliary antenna patterns 180.

The auxiliary pattern 180 illustrated in FIG. 9A corresponds to the main antenna pattern 140 illustrated in FIG. 2A, and the auxiliary pattern 180 illustrated in FIG. 9B corresponds to the main antenna pattern 140 illustrated in FIG. 2B.

First, referring to FIG. 9A, the auxiliary antenna pattern 180 includes two auxiliary patterns 181 and 182. First and second auxiliary patterns 181 and 182 may be apart from each other by a predetermined distance. In a case in which the first and second auxiliary patterns 181 and 182 are extended in the length direction, virtual extension lines of the first and second auxiliary patterns 181 and 182 may coincide with each other. A spacing distance between the first and second auxiliary patterns 181 and 182 may be the same as that between the first and second main patterns 141 and 142.

A length of each of the first and second auxiliary patterns 181 and 182 may be the shorter than that of each of the first and second main patterns 141 and 142. For example, a length of each of the first and second auxiliary patterns 181 and 182 may be a length equal to 85% of a length of each of the first and second main patterns 141 and 142. The main antenna pattern 140 and the auxiliary antenna pattern 180 may coincide with each other in a stacking direction of each layer of the board 110. For instance, in a case in which the main antenna pattern 140 and the auxiliary antenna pattern 180 are directed in an upward direction, they may be overlapped with each other on the same line.

Referring to FIG. 9B, the auxiliary antenna pattern 180 may further include third and fourth auxiliary patterns 183 and 184. The third and fourth auxiliary patterns 183 and 184 may be spaced apart from each other by a predetermined distance. In a case in which the third and fourth auxiliary patterns 183 and 184 are extended in the length direction, virtual extension lines of the third and fourth auxiliary patterns 183 and 184 may coincide with each other. A spacing distance between the third and fourth auxiliary patterns 183 and 184 may be the same as that between the third and fourth main patterns 143 and 144.

In this case, the virtual extension lines of the first and second auxiliary patterns 181 and 182 may intersect virtual extension lines of the third and fourth auxiliary patterns 183 and 184. For instance, the first to fourth auxiliary patterns 141 to 144 may be spaced apart from an intersection point of two virtual lines intersecting each other, by a predetermined distance. Lengths of the third and fourth auxiliary patterns 183 and 184 may be the same as those of the first and second auxiliary patterns 181 and 182.

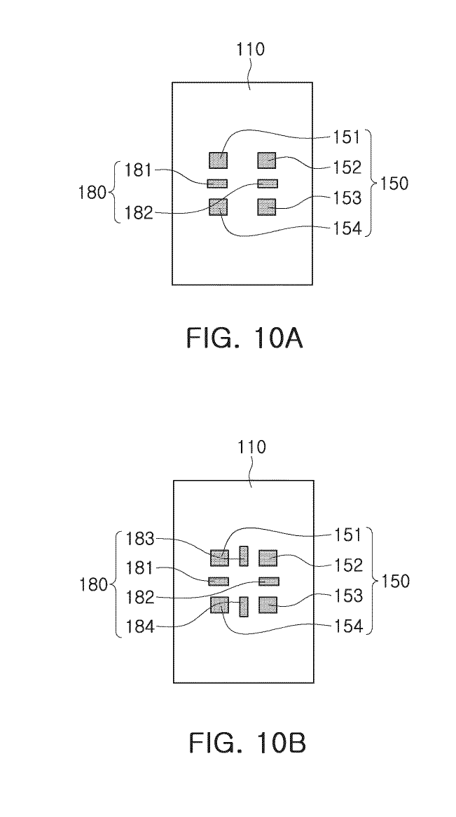

FIGS. 10A and 10B are views illustrating examples of auxiliary antenna patterns 180 and dummy patterns 150.

FIGS. 10A and 10B illustrate a combination of the auxiliary antenna patterns 180 of FIGS. 9A and 9B and the dummy patterns 150 of FIG. 3A when the dummy patterns 150 are formed on the same layer as a layer on which the main antenna patterns 140 are formed. In addition, the auxiliary antenna patterns 180 of FIGS. 9A and 9B may be combined with the dummy patterns of FIGS. 3B and 3C.

The dummy patterns 151 to 154 may be disposed such that sides thereof correspond to sides of the auxiliary patterns 181 to 184, respectively, and may be spaced apart from the sides of the auxiliary patterns 181 to 184 by predetermined distances, respectively, in the length directions of the main patterns. For example, the plurality of dummy patterns 151 to 154 may be disposed to be spaced apart from the sides of the auxiliary patterns 181 to 184 by a distance equal to 1/10 of the wavelength of the signal used with the communications frequency of the antenna 100, in the length directions of the auxiliary patterns 181 to 184, respectively.

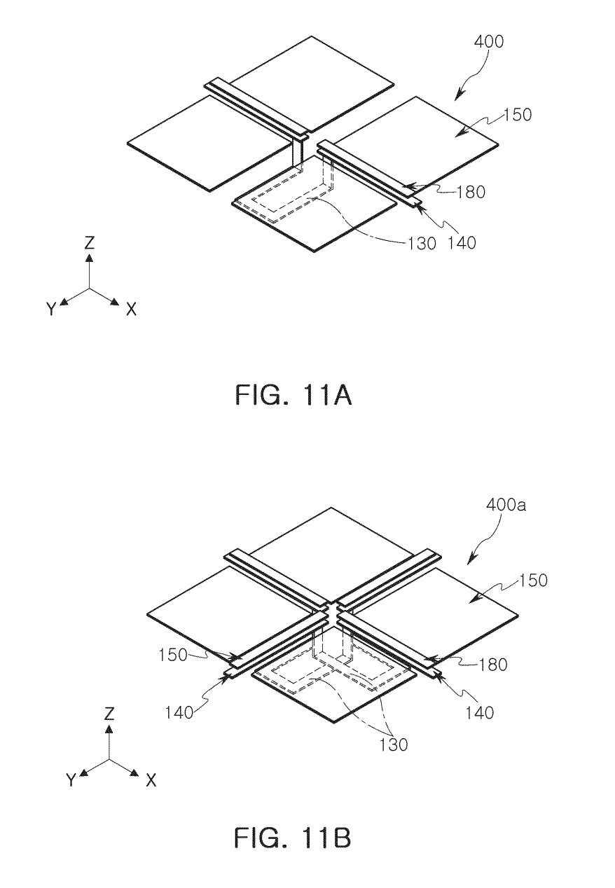

FIGS. 11A and 11B are perspective views illustrating examples of antennas 400 and 400a, respectively, formed by combining respective layers with one another.

Referring to FIG. 11A, the antenna 400 is manufactured by combining the power supply pattern 130 of FIG. 2A, the main antenna pattern 140 and the dummy pattern 150 of FIG. 4A, and the auxiliary antenna pattern 180 of FIG. 9A disposed as illustrated in FIG. 8A.

In addition, referring to FIG. 11B, the antenna 400a is manufactured by combining the power supply pattern 130 of FIG. 2B, the main antenna pattern 140 and the dummy pattern 150 of FIG. 4B, and the auxiliary antenna pattern 180 of FIG. 9B disposed as illustrated in FIG. 8A.

Although not illustrated in FIGS. 11A and 11B, the signal input pattern 120 of FIG. 1 and the reflecting pattern 170 of FIG. 7 disposed as illustrated in FIG. 6A or 6B may also be included in the antenna.

Further, although antennas including a particular combination of layers having a specific form have been illustrated in FIGS. 11A and 11B, antennas including other combinations of layers having the various above-mentioned forms may be manufactured.

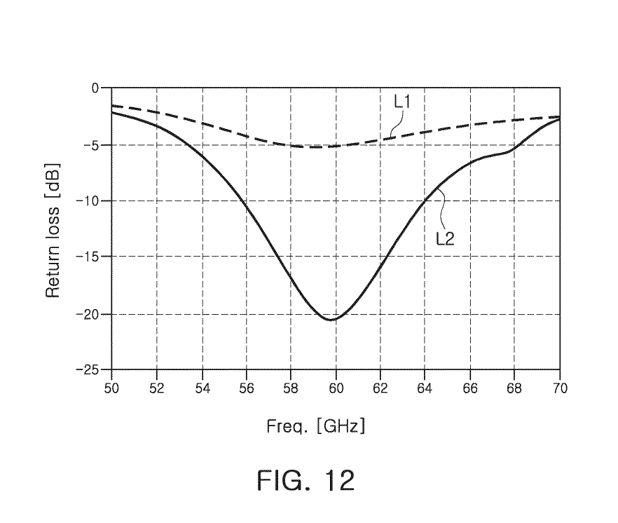

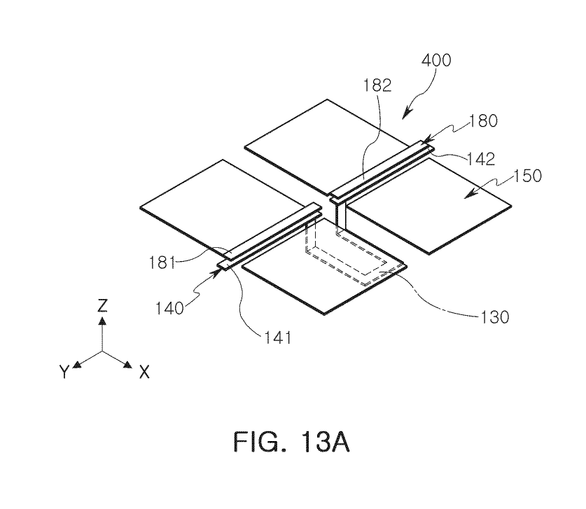

FIG. 12 is a graph illustrating a simulation result of an antenna according to an example disclosed herein. More specifically, FIG. 12 is a graph illustrating return loss characteristics to a frequency.

Referring to FIG. 12, a wider band may be secured in an antenna L2 according to the example disclosed herein than an antenna L1 according to a conventional comparative example, and return loss characteristics of the antenna L2 according to the example disclosed herein may be improved as compared with the antenna L1 according to the conventional comparative example L1.

According to the disclosed example, a bandwidth may be about 14% (in relation to return loss of 10 dB) of a frequency at which the antenna is resonated, and in a case in which return loss is about 6 dB defined in a general antenna, a bandwidth of about 20% may be obtained. For instance, when considering that a bandwidth of about 5% may be secured in an antenna according to the related art, in the antenna according to the example disclosed herein, characteristics of return loss may be improved and a bandwidth may be increased.

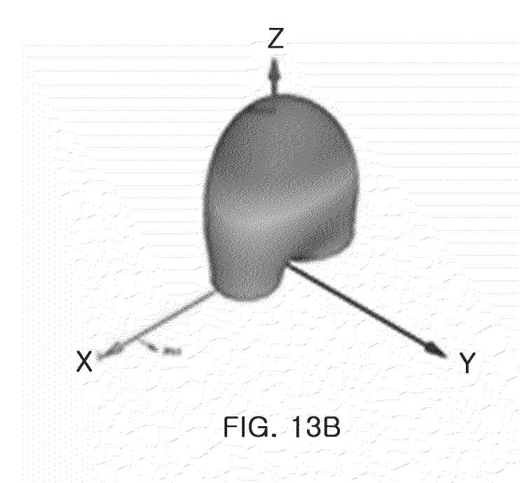

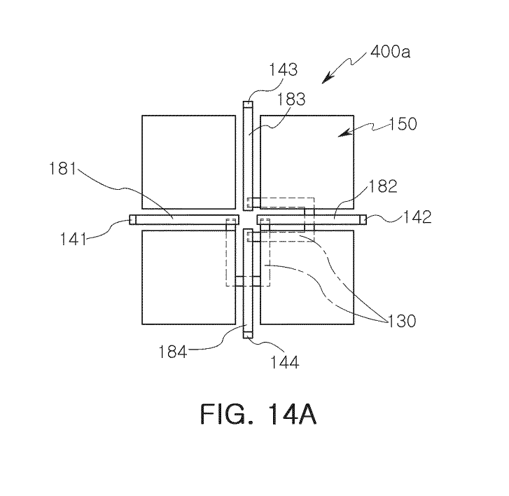

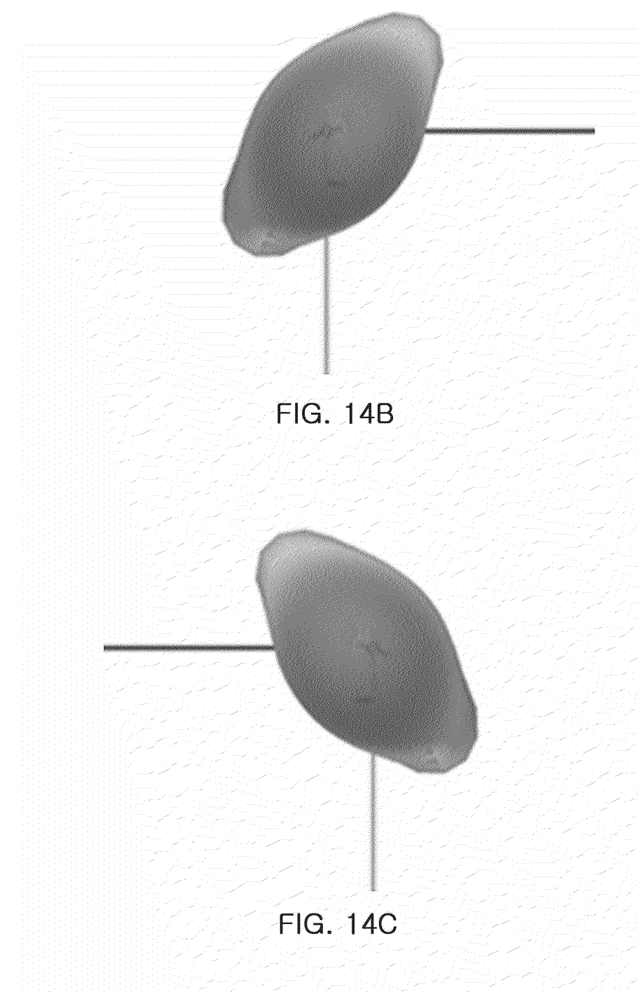

FIGS. 13A through 14C are views illustrating radiation characteristics of an antenna according to an example disclosed herein.

FIG. 13A corresponds to the antenna 400 illustrated in FIG. 11A, and FIG. 13B is a view illustrating radiation characteristics of the antenna 400. Referring to FIGS. 13A and 13B, it may be confirmed that a beam pattern is formed in the same direction as that of the main antenna pattern 140, such that directivity toward a specific direction is formed.

FIG. 14A is a front view of the antenna 400a illustrated in FIG. 11B, and FIGS. 14B and 14C are views illustrating radiation characteristics of the antenna 400a.

In the antenna 400a, in a case in which electricity is fed to one port, for instance, one of a combination of the first and second main patterns 141 and 142 and a combination of the third and fourth main patterns 143 and 144, a beam pattern is formed in the same direction as that of the main patterns to which electricity is fed, similar to FIG. 13B.

However, in the antenna as illustrated in FIG. 14A, in a case in which electricity is fed to both of two ports, radiation characteristics as illustrated in FIGS. 14B and 14C are obtained. In detail, in a case in which in-phase signals are applied to a first port formed by a combination of the first and second main patterns 141 and 142 and a second port formed by a combination of the third and fourth main patterns 143 and 144, a beam pattern as illustrated in FIG. 14B is formed, and in a case in which signals having a phase difference of 180 degrees are applied to the first and second ports, a beam pattern as illustrated in FIG. 14C is formed.

According to the examples of FIGS. 14A-14C, a miniaturization effect that two antennas are disposed in a limited space may be accomplished, and a shape of a beam desired by a system using beam forming may be changed through a phase change in the system without changing a physical structure.

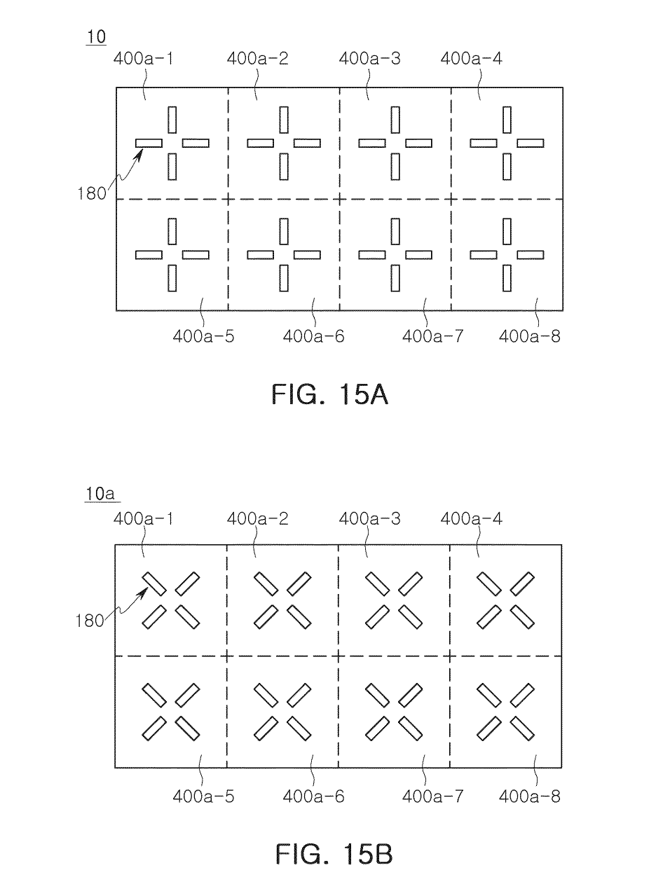

FIGS. 15A and 15B are schematic views of example antenna packages 10 and 10a. The antenna packages 10 and 10a include arrayed antennas 400, each of which is illustrated in FIG. 11B. Alternatively, although not illustrated, an antenna package may include antennas 400, each of which is illustrated in FIG. 11A. Patterns illustrated in the antenna packages of FIGS. 15A and 15B correspond to auxiliary patterns 180 disposed on the uppermost layer of FIG. 11B.

Referring to FIGS. 15A and 15B, the antenna packages 10 and 10a include antennas 400a-1 to 400a-8. The antenna package 10 is disposed such that virtual extension lines of main antenna patterns of antennas neighboring to each other are the same as each other, as illustrated in FIG. 15A. Alternatively, the antenna package 10a is disposed such that virtual extension lines of main antenna patterns of antennas positioned on diagonal lines are the same as each other, as illustrated in FIG. 15B.

An array of the antennas 400a-1 to 400a-8 of the antenna package 10 illustrated in FIG. 15A may correspond to an array when only one of two ports provided in each of the antennas 400a-1 to 400a-8 is used. This may correspond to a case in which a communications module uses the antenna package 10 in each of Tx and Rx paths.

In addition, an array of the antennas 400a-1 to 400a-8 of the antenna package 10a as illustrated in FIG. 15B may correspond to an array when both of the two ports provided in each of the plurality of antennas 400a-1 to 400a-8 are used. This may correspond to a case in which respective antennas share Tx and Rx paths with each other.

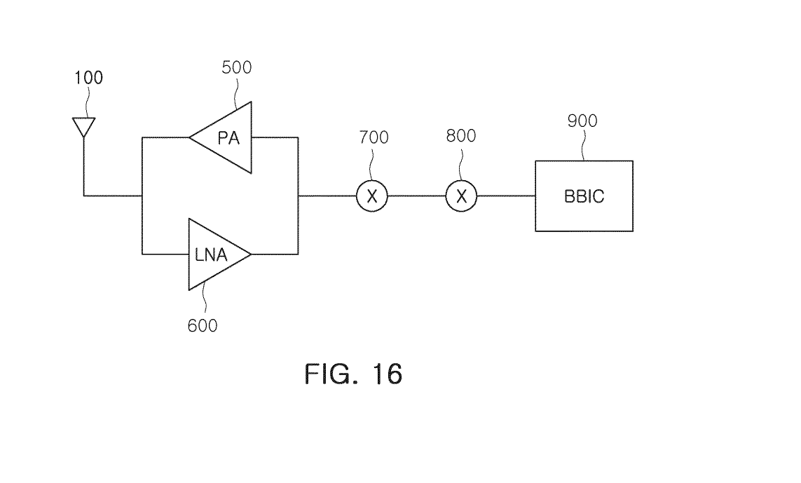

FIG. 16 is a circuit diagram of a communications module 1 according to an example.

Referring to FIG. 16, the communications module 1 according to an example includes at least one antenna 100 transmitting and receiving radio frequency signals, a power amplifier 500 amplifying the radio frequency signals transmitted through the at least one antenna 100, a low noise amplifier 600 amplifying the radio frequency signals received from the at least one antenna 100, a phase modulator 700 modulating phases of the transmitted radio frequency signals and the received radio frequency signals, and a frequency modulator 800 modulating frequencies of the transmitted radio frequency signals and the received radio frequency signals. The frequency modulator 800 is connected to a base band integrated circuit (BBIC) 900. According to alternate examples, the communications module 1 may include an antenna 200, 200a, 300, 300a, 300b, 300c, 300d, 400 or 400a instead of the antenna 100.

According to examples disclosed herein, return loss of an antenna for an extremely high frequency (EHF) band may be decreased, and a bandwidth thereof may be increased. Two independent antennas may be disposed in a space in which one antenna is present, thereby increasing space utilization. Therefore, an array antenna based beam forming system of the next-generation communications system using signals within the EHF band may be further miniaturized. In addition, characteristics of individual antennas may be improved, such that a communications distance may be increased.

Further, a change in antennas depending on characteristics of the beam forming system may be significantly decreased, and system performance may be optimized through only a change in disposition of the antenna.

As set forth above, according to examples disclosed herein, the return loss of the antenna and the antenna package may be decreased, and wideband characteristics of the antenna and the antenna package may be improved.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An antenna comprising:
a board comprising layers;
a main antenna pattern formed on a layer among the layers, and comprising two main patterns spaced apart from each other; and
dummy patterns formed in the board and insulated from the main antenna pattern.

2. The antenna of claim 1, wherein virtual extension lines of the two main patterns, which extend in a length direction of the two main patterns, coincide with each other.

3. The antenna of claim 1, wherein neighboring patterns among the dummy patterns are spaced apart from each other by a predetermined distance.

4. The antenna of claim 1, wherein:
each of the dummy patterns comprises two sides forming a predetermined angle with respect to each other; and
one of the two sides of a first dummy pattern among the dummy patterns and one of the two sides of a second dummy pattern adjacent to the first dummy pattern face each other in parallel with each other.

5. The antenna of claim 1, further comprising at least one auxiliary antenna pattern formed on another layer among the layers that is higher than the layer on which the main antenna pattern is formed.

6. The antenna of claim 5, wherein the auxiliary antenna pattern comprises two auxiliary patterns spaced apart from each other.

7. The antenna of claim 6, wherein the two auxiliary patterns and the two main patterns are overlapped with each other in a stacking direction of the layers.

8. The antenna of claim 1, further comprising a reflecting pattern formed on a layer among the layers that is lower than the layer on which the main antenna pattern is formed.

9. The antenna of claim 1, further comprising a signal input pattern to which a control signal from a radio frequency integrated circuit is input.

10. The antenna of claim 9, further comprising vias forming a power supply path from the signal input pattern to the main antenna pattern.

11. The antenna of claim 1, wherein:
the two main patterns comprise first and second patterns, and
the main antenna pattern further comprises third and fourth patterns positioned on virtual lines intersecting an intersection point of virtual extension lines of the first and second patterns.

12. The antenna of claim 11, further comprising an auxiliary antenna pattern formed on a layer that is higher than the layer on which the main antenna pattern is formed and including four auxiliary patterns overlapped with the first through fourth patterns in a stacking direction.

13. An antenna package comprising antennas, wherein each antenna among the antennas comprises:
a board comprising layers;
an antenna pattern formed on a layer among the layers and comprising two patterns spaced apart from each other; and
dummy patterns insulated from the antenna pattern.

14. The antenna package of claim 13, wherein the antennas are arrayed such that virtual extension lines of the two patterns of respective neighboring antennas, among the antennas, coincide with each other.

15. The antenna package of claim 13, wherein the antennas are arrayed such that the antennas are positioned on diagonal lines, and virtual extension lines of the two patterns of respective neighboring antennas, among the antennas, coincide with each other.

16. A method of manufacturing an antenna, comprising:
disposing a main antenna pattern on a layer among layers of a board, the main antenna pattern comprising two main patterns spaced apart from each other; and
disposing dummy patterns in the board, the dummy patterns being insulated from the main antenna pattern.

17. The method of claim 16, further comprising:
disposing an auxiliary antenna pattern on another layer among the layers, the auxiliary antenna pattern comprising two auxiliary patterns spaced apart from each other; and
arranging the two auxiliary patterns and the two main patterns to be overlapped with each other in a stacking direction of the layers.
